(19) United States
(12) Patent Application Publication
(10) Pub. No.: US 2022/0006322 A1
(43) Pub. Date: Jan. 6, 2022

(54) WIRELESS CHARGER WITH COOLING FUNCTION

(71) Applicant: SHENZHEN SEA STAR SOUNDS CO.,LTD, Shenzhen (CN)

(72) Inventors: Chunyu Chen, Shenzhen (CN); Xianxu Li, Shenzhen (CN); Zhengjun Qiu, Lianyuan (CN)

(21) Appl. No.: 17/447,938

(22) Filed: Sep. 17, 2021

(30) Foreign Application Priority Data
Aug. 25, 2021 (CN) 202122010383.9

(51) Int. Cl. H02J 50/00; H02J 50/10; H05K 7/20

(52) U.S. Cl. CPC H02J 50/005; H05K 7/20909; H02J 50/10

(57) ABSTRACT

The present disclosure provides a wireless charger with a cooling function, including a front shell and a radiating rear shell. A radiating module and a wireless charging coil are mounted in a mounting space enclosed by the front shell and the radiating rear shell. The wireless charging coil and/or the front shell is provided with radiating holes communicated with the mounting space. The wireless charging coil is arranged in the mounting space, and is located at the lower end of the front shell. The radiating module includes: a radiating mechanism and a semiconductor refrigeration sheet. The radiating mechanism is arranged below the wireless charging coil. The semiconductor refrigeration sheet is located between the wireless charging coil and the radiating mechanism. A refrigerating surface of the semiconductor refrigeration sheet faces the wireless charging coil, and a heating surface of the semiconductor refrigeration sheet faces the radiating mechanism.

### TECHNICAL FIELD

The present application relates to the technical field of wireless charging, and in particular, to a wireless charger with a cooling function.

### BACKGROUND

It is to be noted that the contents recorded in this part do not represent the prior art.

A wireless charger refers to a charger that is connected to a terminal device that needs to be charged without using a conventional charging power cord. A newest wireless charging technology is adopted, and electric energy is transmitted by using an alternating magnetic field generated among coils. An inductive coupling technology will become a bridge for connecting a charge between charging base station and a device.

At present, when the wireless charger is used, due to the problems of heating of internal devices and charging heating of a mobile phone, the defects that the charging speed of the wireless charger to the mobile phone is low and the service life of the wireless charger and the service life of the mobile phone are shortened are caused. A cooling structure needs to be used for performing good radiating treatment on the wireless charger and the mobile phone.

### SUMMARY

The present disclosure mainly aims at above-mentioned problems, and provides a wireless charger with a cooling function, which aims to improve the wireless charging efficiency and prolong the service life of the wireless charger with a cooling function and the service life of the mobile phone.

To achieve the above-mentioned objective, the present disclosure provides a wireless charger with a cooling function, including a front shell and a radiating rear shell. A radiating module and a wireless charging coil are mounted in a mounting space enclosed by the front shell and the radiating rear shell.

The wireless charging coil is arranged in the mounting space, and is located at the lower end of the front shell.

The radiating module includes: a radiating mechanism and a semiconductor refrigeration sheet. The radiating mechanism is arranged below the wireless charging coil. The semiconductor refrigeration sheet is located between the wireless charging coil and the radiating mechanism. A refrigerating surface of the semiconductor refrigeration sheet faces the wireless charging coil, and a heating surface of the semiconductor refrigeration sheet faces the radiating mechanism.

Further, a through mounting hole is formed in the front shell. A silicone sheet is arranged on the mounting hole. A heat conducting sheet is arranged between the silicone sheet and the wireless charging coil.

The radiating mechanism includes a radiating fan, a radiating sheet, and a plurality of flaky or columnar radiating fins. The radiating fins are radially arranged on a plate surface of the radiating sheet and enclose the radiating fan therein. The surfaces of the radiating sheet and the radiating fins are all coated with heat conducting materials.

Further, an annular groove is formed in the top of the front shell, and a magnetic ring is arranged in the annular groove.

Further, the radiating module further includes a mounting plate, and a through hole for mounting the semiconductor refrigeration sheet is formed in the center of the mounting plate.

Further, both the outer wall of the magnetic ring and the surface of the wireless charging coil are coated with heat-conducting materials.

Further, the space between the wireless charging coil and a contact surface of the heat conducting sheet is filled with a heat-conducting material.

Further, the mounting space includes an accommodating cavity. A control circuit board and a power supply interface are arranged in the accommodating cavity.

Further, the front shell is connected to the radiating rear shell through buckling and/or gluing.

Further, the front shell is connected to the radiating rear shell through ultrasonic wave and/or gluing.

Compared with the prior art, the present disclosure provides a wireless charger with a cooling function, which has the following advantages:

1. The radiating mechanism is mounted inside the wireless charger, which can release the heat generated by electronic elements and the heating surface of the semiconductor refrigeration sheet inside the to the air.

2. The semiconductor refrigeration sheet is arranged between the wireless charging coil and the radiating mechanism, the refrigerating surface faces the wireless charging coil, and the semiconductor refrigeration sheet refrigerates the wireless charging coil and the mobile phone simultaneously through the heat conducting sheet and the silicone sheet in front of the wireless charging coil, so as to reduce the temperature of the wireless charging coil and the mobile phone.

### BRIEF DESCRIPTION OF THE DRAWINGS

FIG. 1 is a three-dimensional structure of a wireless charger with a cooling function disclosed by the present application.

FIG. 2 is a decomposition structure schematic diagram of a wireless charger with a cooling function disclosed by the present application.

FIG. 3 is a cross-sectional view of a front shell connected to a silicone sheet, a heat conducting sheet, and a magnetic ring.

FIG. 4 is a schematic diagram of a connecting structure between a semiconductor refrigeration sheet and a mounting plate.

FIG. 5 is a schematic diagram of a three-dimensional structure of a radiating mechanism.

Reference signs in the drawings: 1—control circuit board; 2—radiating module; 3—power supply interface; 10—front shell; 11—silicone sheet; 12—heat conducting sheet; 13—magnetic ring; 20—radiating rear shell; 21—radiating mechanism; 22—semiconductor refrigeration sheet; 23—mounting plate; 40—wireless charging coil; 101—mounting hole; 102—annular groove; 201—radiating hole; 202—accommodating cavity; 210—radiating fan; 211—radiating sheet; 212—radiating fin; and 230—through hole.

### DETAILED DESCRIPTION OF THE EMBODIMENTS

The present disclosure is described in detail and technical solutions in the embodiments of the present disclosure will be clearly and completely described with reference to the accompanying drawings. It is apparent that the described embodiments are merely part of the embodiments of the present disclosure, rather than all of the embodiments. On the basis of the embodiments of the present disclosure, all other embodiments obtained by those of ordinary skill in the art without creative work fall within the scope of protection of the present disclosure.

It is to be noted that when a component is described as being “fixed” to another component, it may be directly on the other component, or there may be a component therebetween. When a component is regarded as being “connected” to the other component, it may be directly connected to the other component, or there may be a component therebetween. When a component is regarded as being “arranged” on the other component, it may be directly arranged on the other component, or there may be a component therebetween. The terms “vertical,” “horizontal,” “left,” “right,” and similar expressions used herein are merely for the purpose of illustration.

Unless otherwise defined, all technical and scientific terms used herein shall have the same meanings as commonly understood by those skilled in the art to which the present disclosure belongs. The terms used herein in the specification of the present disclosure are merely used to describe specific embodiments, and are not intended to limit the present disclosure. The term “and/or” used herein includes any and all combinations of one or more of the associated listed items.

Technical solutions of the present disclosure will be described below by taking a mobile phone and a wireless charger with a cooling function of the present application as examples.

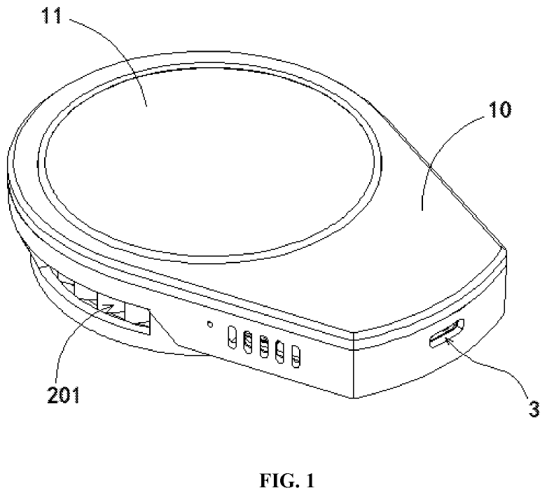

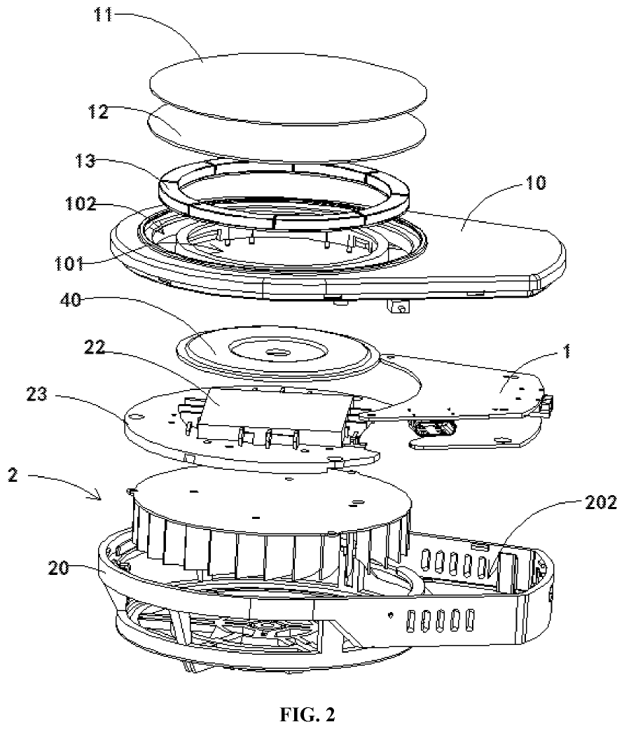

According to the examples of the present disclosure, it can be known from an assembling diagram of FIG. 1 and a decomposition diagram of FIG. 2 that, the wireless charger with a cooling function may include a whole body forming its appearance. The whole body may be formed by a single material or a combination of a plurality of materials, for example, the whole body may include a non-metallic material or a metallic material, for example, plastics, aluminum, stainless steel, copper, or a composite material of a combination thereof.

The compositions of the wireless charger with a cooling function will be described in detail with reference to specific examples.

FIG. 1 to FIG. 5 show schematic diagrams according to specific examples of the present disclosure. As shown in FIG. 1 to FIG. 5, the wireless charger with a cooling function includes a front shell 10 and a radiating rear shell 20. The front shell 10 serves as a front cover of the wireless charger with a cooling function, and a charging area for placing a mobile phone is formed thereon. A magnetic ring 13 used for adsorbing a charged device is arranged on the surface or the inner side of the charging area. The charged device, such as the mobile phone, can be adsorbed through the magnetic ring 13, so that the charged device cannot fall off even when bumping occurs in the charging process. The wireless charger is suitable for use in a running vehicle environment.

The radiating rear shell 20 serves as a rear cover of the wireless charger with a cooling function, and encloses with the front shell 10 to form a mounting space for electronic elements. In the embodiment, the electronic elements include a wireless charging coil 40, a radiating mechanism 21, a semiconductor refrigeration sheet 22, a control circuit board 1, etc. The wireless charging coil 40 and the control circuit board 1 form a communication circuit. Energy is transmitted to the charged device by the wireless charging coil 40 in the form of a magnetic field. The heat generated in the mounting space by the semiconductor refrigeration sheet 22 and the control circuit board 1 in a working state is discharged from radiating holes 201 of the rear radiating shell 20 by the radiating mechanism 21.

In the above-mentioned embodiment, the wireless charging coil 40 is located at the lower end of the front shell 10, which can reduce the charging distance between the wireless charging coil 40 and a mobile phone device. The refrigerating surface of the semiconductor refrigeration sheet 22 is closely attached to the wireless charging coil 40, so as to reduce the heat generated by the wireless charging coil 40 during working and the mobile phone. The heating surface of the semiconductor refrigeration sheet 22 is closely attached to the radiating mechanism 21. The heat generated by the semiconductor refrigeration sheet 22 and the control circuit board 1 is extracted from the radiating holes 201 by the radiating mechanism 21, and an air flow is formed inside the radiating holes 201, so as that the radiating performance of the wireless charger with a cooling function is further improved.

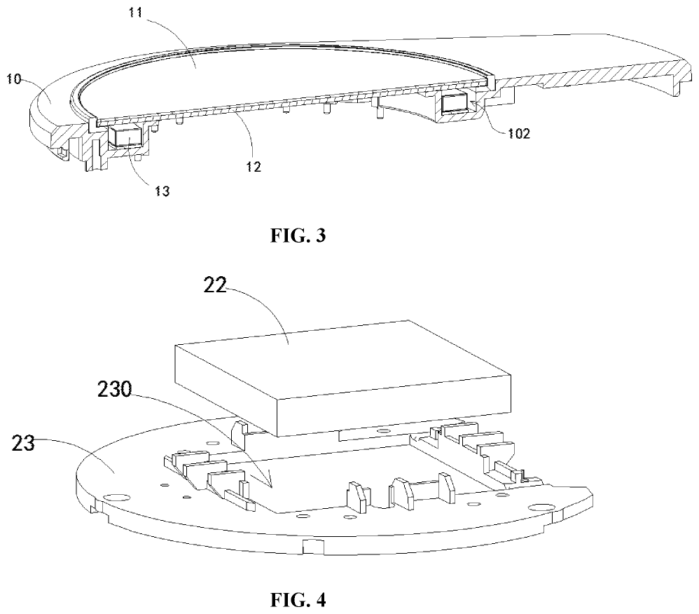

As shown in FIG. 2 and FIG. 3, a through mounting hole 101 is formed in a charging position of the front shell 10. A silicone sheet 11 with a heat conducting material is arranged on the mounting hole 101. A heat conducting sheet 12 is arranged between the silicone sheet 11 and the wireless charging coil 40. The heat conducting sheet 12 is mainly used for the silicone sheet 11 with a flat surface, so as to keep the attractiveness of the wireless charger. In some embodiments, the heat conductivity coefficient of the silicone sheet 11 is greater than or equal to 4, such as heat conducting silicone, heat conducting plastics, etc. In some embodiments, heat conductivity coefficient of the heat conducting sheet 12 is greater than or equal to 4, such as heat conducting ceramics, heat conducting plastics, etc. In some embodiments, the heat conducting sheet 12 may be omitted when the flatness of a material of the silicone sheet is good.

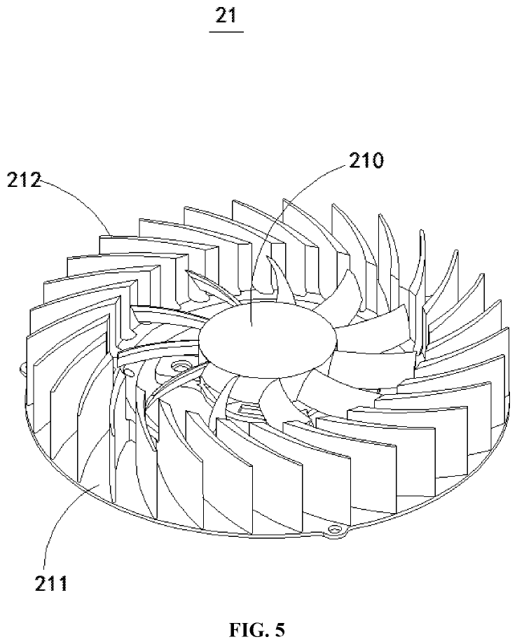

FIG. 5 is a schematic diagram of a three-dimensional structure of the radiating mechanism 21. It can be seen from the figure that the radiating mechanism 21 includes a radiating fan 210, a radiating sheet 211, and a plurality of flaky or columnar radiating fins 212. The plurality of radiating fins 212 are radially arranged on a plate surface of the radiating sheet 211 to enclose the radiating fan 210 inside. The radiating fins 212 are vertically or horizontally connected to the radiating sheet 211 at a certain spiral angle. The radiating sheet 211 is tightly attached to the semiconductor refrigeration sheet 22, so that the heat generated by the semiconductor refrigeration sheet 22 is absorbed onto the radiating sheet 211 coated with the heat conducting coating for radiating. In order to improve the heat conducting efficiency, the surfaces of the radiating sheet 211, the radiating fins 212, the magnetic ring 13, and the wireless charging coil 40 are coated with a layer of heat conduction material. The space between the wireless charging coil 40 and the contact surface of the heat conducting sheet 12 is filled with a heat conducting material, so as to conduct part heat out and improve a radiating effect.

As shown in FIG. 1 and FIG. 2, an annular groove 102 is formed in the top of the front shell 10. The magnetic ring 13 in the above-mentioned example is arranged in the annular groove 102 and is closed by the heat conducting sheet 12 and the silicone sheet 11. After the magnetic ring 13 is mounted in the annular groove 102, gap may be filled by using a heat conducting colloid or filler, so as to increase the contact area and enhance heat conduction.

FIG. 4 is a schematic diagram of a connecting structure between the semiconductor refrigeration sheet 22 and the mounting plate 23. A through hole 230 for mounting the semiconductor refrigeration sheet 22 is formed in the center of the mounting plate 23, and the semiconductor refrigeration sheet 22 is in the shape of a circle, a square, a regular polygon or other shapes, so as to facilitate the product mounting and layout to be closely attached to the wireless charging coil 40 and the radiating sheet 211.

In addition, the front shell 10 is provided with a clamping part. The radiating rear shell 20 is provided with a clamping position connected with the clamping part. A mounting space enclosed after the front shell 10 and the radiating rear shell 20 are connected includes an accommodating cavity 202. The control circuit board 1 and a power supply interface 3 are arranged in the accommodating cavity 202, so as to avoid touching a cold surface or a hot surface of the semiconductor refrigeration sheet 22 by mistake.

Working principle: during use, a user places the mobile phone on the top of the silicon sheet 11, the wireless charging coil 40 transmits energy for the mobile phone. In a working state, the radiating fan 210 of the radiating module and the semiconductor refrigeration sheet 22 are started. Refrigerating and cooling operations are performed by using the refrigerating surface of the semiconductor refrigeration sheet 22, and the heat of the heating surface is discharged by the radiating mechanism 21. The interior or the exterior of the wireless charger with a cooling function is coated or filled with various radiating materials, which can achieve an effects of enhancing heat conduction, and finally, greatly improve the wireless charging efficiency and the service life of the whole wireless charger and the mobile phone.

Through the reading and understanding of the above-mentioned specific implementation manner, those skilled in the art can easily realize the present disclosure. However, it is to be noted that the present disclosure is not limited to the specific implementation manner. On the basis of the disclosed implementation manner, a person skilled in the basic art can arbitrarily combine different technical features, so as to realize different technical solutions. For example, when a charged device is detected by arranging various sensors, a charging function of the wireless charging coil 40 and the cooling function of the semiconductor refrigeration sheet 22 and the radiating mechanism 21 may be started. Of course, the cooling function of the semiconductor refrigeration sheet 22 and the radiating mechanism 21 may also be delayed to start, and other technical solutions may also be formed by combining the cooling function of the semiconductor refrigeration sheet 22 and the radiating mechanism 21. For example, the radiating mechanism 21 may work in advance of the semiconductor refrigeration sheet 22 to ensure that the semiconductor refrigeration sheet 22 starts and works at a proper working temperature, so as to prolong the service life of the semiconductor refrigeration sheet 22. In addition, the wireless charger with a cooling function may also prompt through an indicator lamp, or screen display, or sound when the radiating mechanism 21 stops working or an internal temperature exceeds a safety range due to other causes by arranging a temperature protection sensing element. Therefore, the scope of protection of the present application is merely limited by the scope of the appended claims.

The present disclosure is elaborated above by applying specific examples, which is merely used to help understand the present disclosure and is not used to limit the present disclosure. For those skilled in the art to which the present disclosure belongs, a plurality of simple deductions, deformations or replacement can also be made according to the idea of the present disclosure.

What is claimed is:

1. A wireless charger with a cooling function, comprising a front shell and a radiating rear shell, a radiating module and a wireless charging coil being mounted in a mounting space enclosed by the front shell and the radiating rear shell, and the radiating rear shell and/or the front shell being provided with radiating holes communicated with the mounting space, wherein
the wireless charging coil is arranged in the mounting space, and is located at the lower end of the front shell;
the radiating module comprises: a radiating mechanism and a semiconductor refrigeration sheet; the radiating mechanism is arranged below the wireless charging coil; the semiconductor refrigeration sheet is located between the wireless charging coil and the radiating mechanism; and a refrigerating surface of the semiconductor refrigeration sheet faces the wireless charging coil, and a heating surface of the semiconductor refrigeration sheet faces the radiating mechanism.

2. The wireless charger with a cooling function according to claim 1, wherein a through mounting hole is formed in the front shell; a silicone sheet is arranged on the mounting hole; and a heat conducting sheet is arranged between the silicone sheet and the wireless charging coil.

3. The wireless charger with a cooling function according to claim 1, wherein the radiating mechanism comprises a radiating fan, a radiating sheet, and a plurality of flaky or columnar radiating fins; the radiating fins are radially arranged on a plate surface of the radiating sheet and enclose the radiating fan therein; and the surfaces of the radiating sheet and the radiating fins are all coated with heat conducting materials.

4. The wireless charger with a cooling function according to claim 1, wherein an annular groove is formed in the top of the front shell, and a magnetic ring is arranged in the annular groove.

5. The wireless charger with a cooling function according to claim 1, wherein the radiating module further comprises a mounting plate; and a through hole for mounting the semiconductor refrigeration sheet is formed in the center of the mounting plate.

6. The wireless charger with a cooling function according to claim 4, wherein both the outer wall of the magnetic ring and the surface of the wireless charging coil are coated with heat-conducting materials.

7. The wireless charger with a cooling function according to claim 2, wherein the space between the wireless charging coil and a contact surface of the heat conducting sheet is filled with a heat-conducting material.

8. The wireless charger with a cooling function according to claim 1, wherein the mounting space comprises an accommodating cavity; and a control circuit board and a power supply interface are arranged in the accommodating cavity.

9. The wireless charger with a cooling function according to claim 1, wherein the front shell is connected to the radiating rear shell by buckling and/or gluing.

10. The wireless charger with a cooling function according to claim 1, wherein the front shell is connected to the radiating rear shell through ultrasonic wave and/or gluing.
